(19) United States
(12) Patent Application Publication
(10) Pub. No.: US 2024/0333146 A1
(43) Pub. Date: Oct. 3, 2024

(54) SEMICONDUCTOR INTEGRATED CIRCUIT

(71) Applicant: ROHM CO., LTD., Kyoto (JP)

(72) Inventor: Hisashi SUGIE, Kyoto (JP)

(21) Appl. No.: 18/607,708

(22) Filed: Mar. 18, 2024

(30) Foreign Application Priority Data
Mar. 29, 2023 (JP) 2023-054392

(51) Int. Cl. H02M 3/07

(52) U.S. Cl. CPC H02M 3/07; H01L 28/60

(57) ABSTRACT

A flying capacitor includes a pair of comb-shaped electrodes, which are formed in a metal wiring layer and distanced from each other by a gap. In a semiconductor substrate, a well is formed in a region overlapping with the flying capacitor. The well is electrically connected to one of the pair of comb-shaped electrodes corresponding to one end of the flying capacitor driven by a driver.

### CROSS-REFERENCE TO RELATED APPLICATIONS

The present invention claims priority under 35 U.S.C. § 119 to Japanese Application No. 2023-054392, filed on Mar. 29, 2023, the entire contents of which being incorporated herein by reference.

### TECHNICAL FIELD

The present disclosure relates to a semiconductor integrated circuit including a charge pump circuit.

### BACKGROUND

In a semiconductor integrated circuit, when a voltage higher than a power supply voltage is required, a charge pump circuit is used. The charge pump circuit generates the voltage higher than the power supply voltage by repeating an operation of storing charges in a flying capacitor and transferring the stored charges to an output capacitor.

### BRIEF DESCRIPTION OF DRAWINGS

The accompanying drawings, which are incorporated in and constitute a part of the specification, illustrate embodiments of the present disclosure.

FIG. 1 is a circuit diagram of a semiconductor integrated circuit including a charge pump circuit according to embodiments.

FIG. 2 is a perspective view of a semiconductor integrated circuit including a flying capacitor according to Embodiment 1.

FIG. 3 is a cross-sectional view of the semiconductor integrated circuit including the flying capacitor according to Embodiment 1.

FIG. 4 is a cross-sectional view of a semiconductor integrated circuit including a flying capacitor according to a comparative technique.

FIG. 5 is an equivalent circuit diagram of a charge pump circuit including the flying capacitor shown in FIG. 4.

FIG. 6 is a circuit diagram of a charge pump circuit that takes a parasitic capacitance into consideration.

FIG. 7 is a perspective view of a semiconductor integrated circuit including a flying capacitor according to Modification 1-1.

FIG. 8 is a cross-sectional view of the semiconductor integrated circuit including the flying capacitor according to Modification 1-1.

FIG. 9 is a cross-sectional view of a semiconductor integrated circuit including a flying capacitor according to Modification 1-2.

FIG. 10 is a perspective view of a semiconductor integrated circuit including a flying capacitor according to Embodiment 2.

FIG. 11 is a cross-sectional view of the semiconductor integrated circuit including the flying capacitor according to Embodiment 2.

FIG. 12 is a circuit diagram of a charge pump circuit that takes a parasitic capacitance into consideration.

FIG. 13 is a cross-sectional view of a semiconductor integrated circuit including a flying capacitor according to Modification 2-2.

FIG. 14 is a circuit diagram of a semiconductor integrated circuit.

FIG. 15 is a circuit diagram of a motor driver circuit including a charge pump circuit.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### SUMMARY OF EMBODIMENTS

A summary of some exemplary embodiments of the present disclosure will be described. This Summary is intended to provide a simplified description of some concepts of one or more embodiments in order to provide a basic understanding of the embodiments as a prelude to the following detailed description and is not intended to limit the breadth of the invention or the disclosure. This summary is not an exhaustive overview of all conceivable embodiments and is not intended to identify key elements of all embodiments or to delineate the scope of any or all embodiments. For the sake of convenience, “one embodiment” may be used to refer to one embodiment (example or modification) or multiple embodiments (examples or modifications) disclosed in this specification.

In a semiconductor integrated circuit according to one embodiment, a charge pump circuit is integrated on a semiconductor substrate. The charge pump circuit includes a flying capacitor, and a driver configured to apply a switching voltage to one end of the flying capacitor. The flying capacitor includes a pair of comb-shaped electrodes, which are formed in a metal wiring layer and distanced from each other by a gap. A well is formed in the semiconductor substrate in a region overlapping with the flying capacitor. The well is electrically connected to one of the pair of comb-shaped electrodes corresponding to the one end.

With this configuration, it is possible to reduce a parasitic capacitance between the pair of comb-shaped electrodes forming the flying capacitor and the semiconductor substrate. Thus, it is possible to reduce leakage of charges via the parasitic capacitance and to improve efficiency.

In one embodiment, the pair of comb-shaped electrodes may have a multilayer structure.

In one embodiment, the flying capacitor may further include a rectangular electrode formed in an uppermost metal wiring layer. Thus, it is possible to increase a capacity of the flying capacitor.

In one embodiment, the rectangular electrode may be electrically connected to one of the pair of comb-shaped electrodes corresponding to the one end. With this configuration, since the rectangular electrode is connected to the well, an impedance of the well appears to be smaller than in a case where there is no rectangular electrode. Thus, it is possible to further reduce the leakage of charges via the parasitic capacitance.

A semiconductor integrated circuit according to one embodiment is configured such that a charge pump circuit is integrated on a semiconductor substrate. The charge pump circuit includes a flying capacitor, and a driver configured to apply a switching voltage to one end of the flying capacitor. The flying capacitor includes a pair of comb-shaped electrodes, which are formed in a metal wiring layer and distanced from each other by a gap, and a lower rectangular electrode formed in a layer below the metal wiring layer. The lower rectangular electrode is electrically connected to one of the pair of comb-shaped electrodes corresponding to the one end.

With this configuration, it is possible to reduce a parasitic capacitance between the pair of comb-shaped electrodes forming the flying capacitor and the semiconductor substrate. Thus, it is possible to reduce leakage of charges via the parasitic capacitance and to improve efficiency.

In one embodiment, the pair of comb-shaped electrodes may have a multilayer structure.

In one embodiment, the flying capacitor may further include an upper rectangular electrode formed in an uppermost metal wiring layer. Thus, it is possible to increase a capacity of the flying capacitor.

In one embodiment, the upper rectangular electrode may be electrically connected to one of the pair of comb-shaped electrodes corresponding to the one end. With this configuration, since the upper rectangular electrode is connected to the lower rectangular electrode, an impedance of the lower rectangular electrode appears to be smaller than in a case where there is no upper rectangular electrode. Thus, it is possible to further reduce the leakage of charges via the parasitic capacitance.

In one embodiment, the semiconductor integrated circuit may be a motor driver circuit. The semiconductor integrated circuit may further include a logic circuit configured to generate a control signal for instructing a high-side transistor to be turned-on and turned-off, and a high-side pre-driver configured to drive the high-side transistor in response to the control signal. The high-side pre-driver may include a charge pump circuit connected to a gate of the high-side transistor via an output line, and configured to generate a step-up voltage in response to a clock signal and supply the step-up voltage to the gate of the high-side transistor, and a charge control circuit configured to operate the charge pump circuit in response to a transition of the control signal to an on state that instructs the high-side transistor to be turned on.

### EMBODIMENTS

Hereinafter, embodiments will be described with reference to the drawings. Identical or equivalent components, members, and processes shown in each drawing are designated by like reference numerals, and redundant descriptions thereof will be omitted as appropriate. Further, the embodiments are exemplary rather than limiting the disclosure and the invention. All features and combinations thereof described in the embodiments are not necessarily essential to the disclosure and the invention.

In the present disclosure, “a state where a member A is connected to a member B” includes a case where the member A and the member B are physically and directly connected or even a case where the member A and the member B are indirectly connected via any other member that does not affect an electrical connection state between the members A and B or does not impair functions and effects achieved by combinations of the members A and B.

Similarly, “a state where a member C is installed between a member A and a member B” includes a case where the member A and the member C or the member B and the member C are indirectly connected via any other member that does not affect an electrical connection state between the members A and C or the members B and C or does not impair functions and effects achieved by combinations of the members A and C or the members B and C, in addition to a case where the member A and the member C or the member B and the member C are directly connected.

Further, vertical and horizontal axes of waveform diagrams and time charts shown in this specification are enlarged or reduced as appropriate for the ease of understanding. Each waveform shown is also simplified for the ease of understanding.

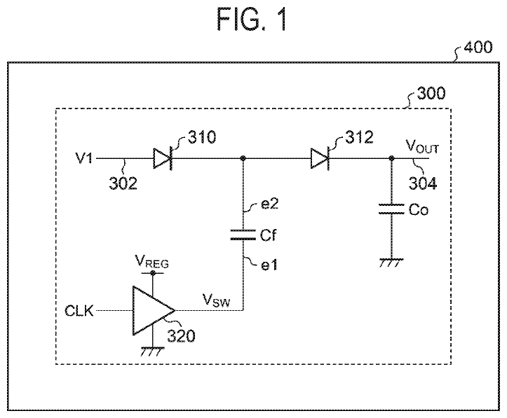

FIG. 1 is a circuit diagram of a semiconductor integrated circuit 400 including a charge pump circuit 300 according to embodiments. The charge pump circuit 300 is monolithically integrated on a semiconductor substrate and is one of functional blocks of the semiconductor integrated circuit 400.

The charge pump circuit 300 includes a flying capacitor Cf, an output capacitor Co, a driver 320, and rectifying elements 310 and 312. A configuration of the charge pump circuit 300 shown here is an example, and an application of the present disclosure is not limited to the charge pump circuit 300 having a specific structure.

The charge pump circuit 300 receives a voltage V1 via an input line 302. The charge pump circuit 300 generates a step-up voltage Vout, which is obtained by adding a voltage V2 to the voltage V1, on an output line 304. When V2=V1, the charge pump circuit 300 becomes a doubled charge pump circuit.

The driver 320 applies a switching voltage Vsw to a first end e1 of the flying capacitor Cf in synchronization with a clock signal CLK. A second end e2 of the flying capacitor Cf is connected to the input line 302 via the rectifying element 310. In addition, the second end e2 of the flying capacitor Cf is connected to the output line 304 via the rectifying element 312. The rectifying elements 310 and 312 may be diodes, or may be transistors that are switched in synchronization with the clock signal CLK.

The flying capacitor Cf is integrated on the semiconductor substrate. Hereinafter, a structure of the flying capacitor Cf will be described in several embodiments.

### Embodiment 1

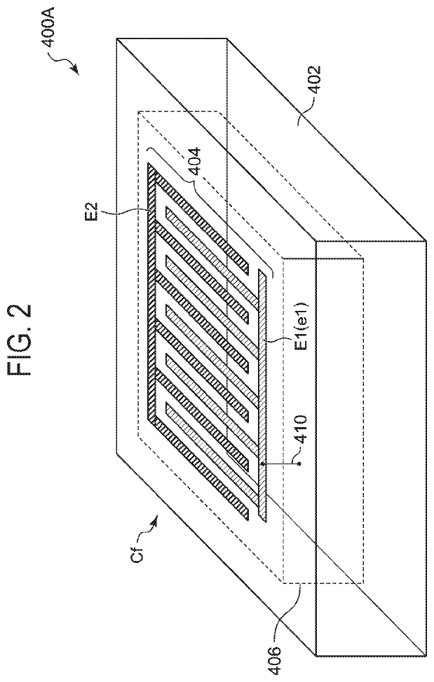

FIG. 2 is a perspective view of a semiconductor integrated circuit 400A including a flying capacitor Cf according to Embodiment 1. The semiconductor integrated circuit 400A includes a semiconductor substrate 402 and at least one metal wiring layer 404 formed on the semiconductor substrate 402. The metal wiring layer 404 is, for example, an aluminum wiring layer.

The flying capacitor Cf is a metal capacitance formed using the metal wiring layer 404. The flying capacitor Cf includes a pair of comb-shaped electrodes E1 and E2, which are formed in the same metal wiring layer 404 and distanced from each other by a gap. The first comb-shaped electrode E1 corresponds to the first end e1 of the flying capacitor Cf to which the switching voltage Vsw is applied in FIG. 1. The second comb-shaped electrode E2 corresponds to the second end e2 of the flying capacitor Cf connected to the rectifying elements 310 and 312 in FIG. 1.

A well 406 is formed in the semiconductor substrate 402 in a region overlapping with the flying capacitor. The well 406 corresponds to the first end e1 of the flying capacitor Cf and is electrically connected to the first electrode E1 of the pair of comb-shaped electrodes E1 and E2. A solid line 410 in FIG. 2 schematically shows an electrical connection between the well 406 and the comb-shaped electrode E1.

The above is a configuration of the semiconductor integrated circuit 400A.

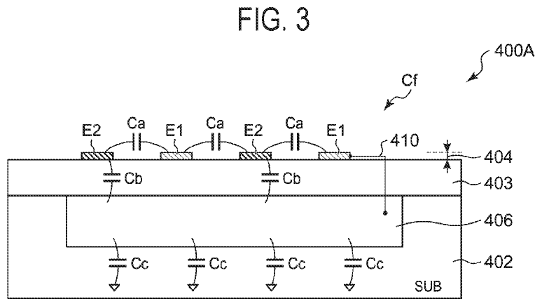

FIG. 3 is a cross-sectional view of the semiconductor integrated circuit 400A including the flying capacitor Cf according to Embodiment 1.

An effective capacitance Ca of the flying capacitor Cf is formed between the first comb-shaped electrode E1 and the second comb-shaped electrode E2.

An insulating layer (interlayer insulating film) 403 exists between the semiconductor substrate 402 and the metal wiring layer 404. A parasitic capacitance Cb is formed between the second comb-shaped electrode E2 and the well 406. Further, a parasitic capacitance Cc is formed between the well 406 and the semiconductor substrate 402.

Advantages of the semiconductor integrated circuit 400A will become apparent when compared with a comparative technique. Thus, the comparative technique will be described.

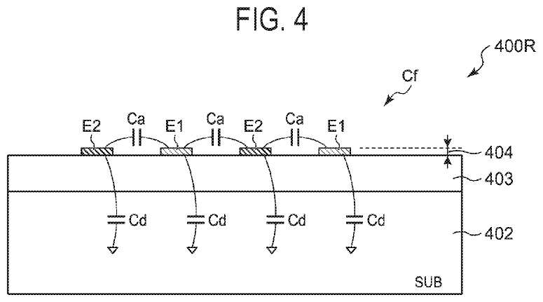

FIG. 4 is a cross-sectional view of a semiconductor integrated circuit 400R including a flying capacitor Cf according to a comparative technique. The flying capacitor Cf according to the comparative technique differs from that of FIG. 3 in that no well is formed. In the comparative technique, parasitic capacitances Cd are formed between the first comb-shaped electrode E1 and the semiconductor substrate 402 and between the second comb-shaped electrode E2 and the semiconductor substrate 402.

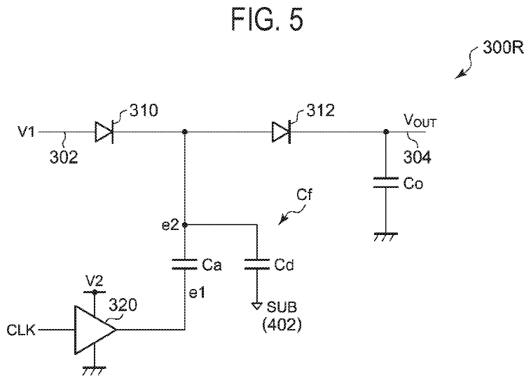

FIG. 5 is an equivalent circuit diagram of a charge pump circuit 300R including the flying capacitor Cf shown in FIG. 4. In the comparative technique, the parasitic capacitance Cd exists between the second end e2 of the flying capacitor Cf and the semiconductor substrate 402. Since the second end e2 of the flying capacitor Cf is a high impedance node, the second end e2 of the flying capacitor Cf is easily affected by the parasitic capacitance Cd. As a result, charges leak from the second end e2 toward the semiconductor substrate 402 via the parasitic capacitance Cd, thereby reducing efficiency of the charge pump circuit 300R.

Returning to Embodiment 1, advantages thereof will be described.

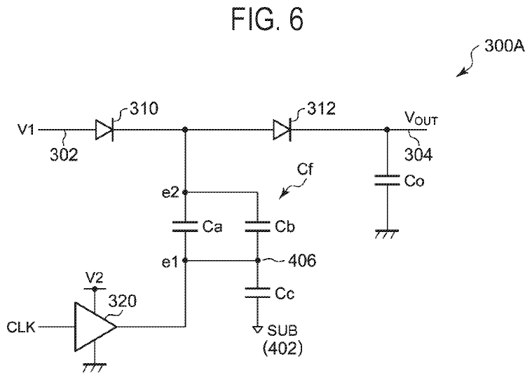

FIG. 6 is a circuit diagram of a charge pump circuit 300A that takes parasitic capacitance into consideration. The flying capacitor Cf includes capacitances Ca, Cb, and Cc. The capacitance Ca is the inter-electrode capacitance Ca shown in FIG. 3, and the capacitances Cb and Cc are parasitic capacitances.

By connecting the well 406 to the first end e1 of the flying capacitor Cf, the parasitic capacitance Cb of the parasitic capacitances Cb and Cc of the flying capacitor Cf is connected in parallel with the inter-electrode capacitance Ca. In other words, the parasitic capacitance Cb can be effectively used as an effective capacitance of the flying capacitor Cf.

In this flying capacitor Cf, the parasitic capacitance Cc serves as a charge leakage path. The parasitic capacitance Cc is connected to the first end e1 of the flying capacitor Cf, i.e., an output node of the driver 320. The first end e1 of the flying capacitor Cf is a low impedance node. Therefore, the first end e1 of the flying capacitor Cf is difficult to be affected by the parasitic capacitance Cc, and the leakage of charges is reduced compared with the comparative technique. Thus, it is possible to improve efficiency of the charge pump circuit 300A.

Further, as shown in FIG. 3, since the parasitic capacitance Cb is caused by the insulating layer 403, a relationship of Cb>Cc is established. In other words, the parasitic capacitance Cc is sufficiently smaller than the parasitic capacitance Cd shown in FIG. 4. Therefore, in the charge pump circuit 300A of FIG. 6, the leakage of charges via the parasitic capacitance Cc is reduced compared with the comparative technique. Thus, it is possible to improve the efficiency of the charge pump circuit 300A.

Next, modifications of the flying capacitor Cf will be described.

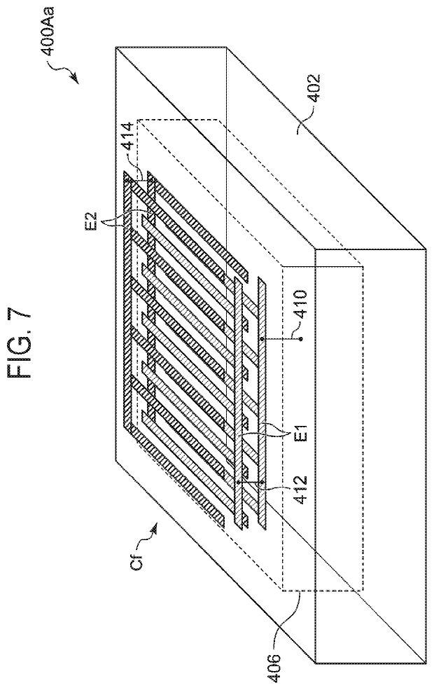

FIG. 7 is a perspective view of a semiconductor integrated circuit 400Aa including a flying capacitor Cf according to Modification 1-1. In Modification 1-1, the first comb-shaped electrode E1 and the second comb-shaped electrode E2 have a multilayer structure. In this example, the first comb-shaped electrode E1 and the second comb-shaped electrode E2 have a two-layer structure, but they may have three or more layers. In the figure, a line 412 indicates that different wiring layers in the first comb-shaped electrodes E1 are electrically connected to each other. A line 414 indicates that different wiring layers in the second comb-shaped electrodes E2 are electrically connected to each other.

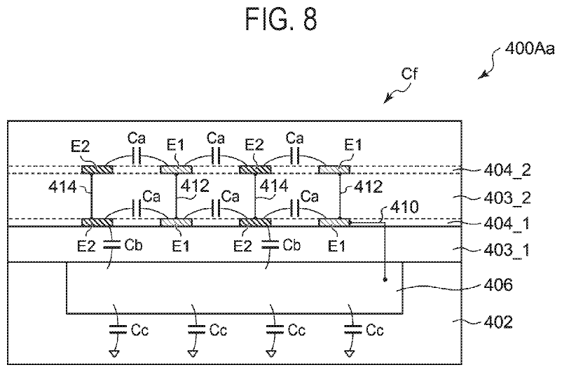

FIG. 8 is a cross-sectional view of the semiconductor integrated circuit 400Aa including the flying capacitor Cf according to Modification 1-1. According to this flying capacitor Cf, an effective capacitance Ca can be increased by forming the comb-shaped electrode into a multilayer structure.

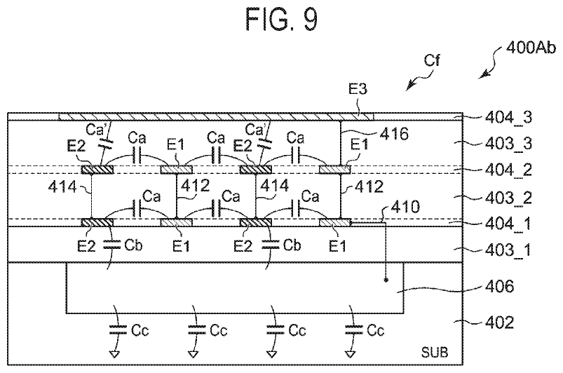

FIG. 9 is a cross-sectional view of a semiconductor integrated circuit 400Ab including a flying capacitor Cf according to Modification 1-2. The flying capacitor Cf further includes a rectangular electrode E3 formed in an uppermost metal wiring layer 404_3. The rectangular electrode E3 is electrically connected to the first comb-shaped electrode E1. A solid line 416 schematically indicates an electrical connection between the rectangular electrode E3 and the first comb-shaped electrode E1. The rectangular electrode E3 is a quadrangle that covers a formation region of the first comb-shaped electrode E1 and the second comb-shaped electrode E2.

In this modification, a capacitance Ca′ is also formed between the second comb-shaped electrode E2 and the rectangular electrode E3, which makes it possible to increase an effective capacitance of the flying capacitor Cf. Further, the rectangular electrode E3 has a larger area than the first comb-shaped electrode E1 and the second comb-shaped electrode E2. Therefore, an effect of reducing an impedance of the first end e1 of the flying capacitor Cf can be obtained, and leakage of charges to the semiconductor substrate 402 can be further reduced.

### Embodiment 2

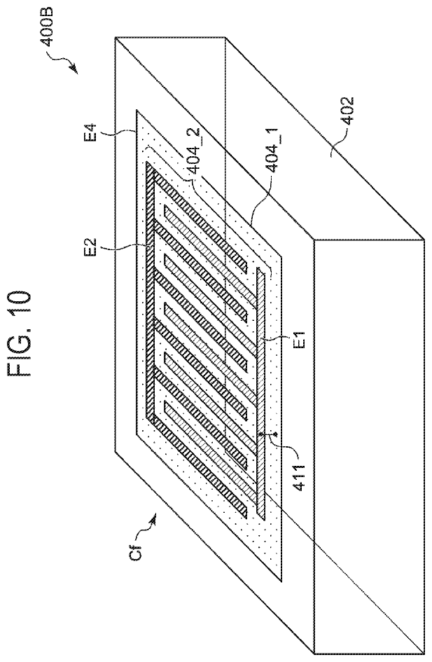

FIG. 10 is a perspective view of a semiconductor integrated circuit 400B including a flying capacitor Cf according to Embodiment 2. The semiconductor integrated circuit 400B includes a semiconductor substrate 402 and a plurality of metal wiring layers 404_1 and 404_2 formed on the semiconductor substrate 402.

The flying capacitor Cf is a metal capacitance formed using the metal wiring layers 404_1 and 404_2. The flying capacitor Cf includes a pair of comb-shaped electrodes E1 and E2, which are formed in the same metal wiring layer 404_2 and distanced from each other by a gap. The first comb-shaped electrode E1 corresponds to the first end e1 of the flying capacitor Cf in FIG. 1 to which the switching voltage Vsw is applied. The second comb-shaped electrode E2 corresponds to the second end e2 of the flying capacitor Cf in FIG. 1 connected to the rectifying elements 310 and 312.

The flying capacitor Cf further includes a lower rectangular electrode E4. The lower rectangular electrode E4 is formed in the metal wiring layer 404_1 below the metal wiring layer 404_2 where the comb-shaped electrodes E1 and E2 are formed. The lower rectangular electrode E4 is a quadrangle that covers a formation region of the first comb-shaped electrode E1 and the second comb-shaped electrode E2.

The lower rectangular electrode E4 corresponds to the first end e1 of the flying capacitor Cf and is electrically connected to the electrode E1 of the pair of comb-shaped electrodes E1 and E2. A solid line 411 in FIG. 10 schematically indicates an electrical connection between the lower rectangular electrode E4 and the comb-shaped electrode E1.

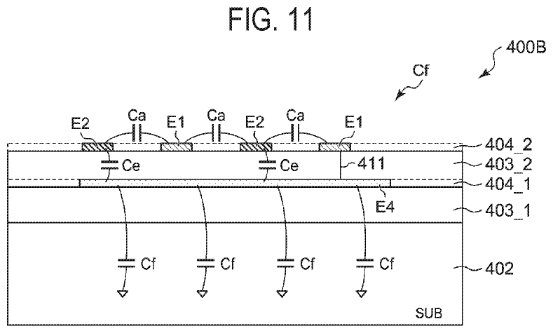

FIG. 11 is a cross-sectional view of the semiconductor integrated circuit 400B including the flying capacitor Cf according to Embodiment 2.

An effective capacitance Ca of the flying capacitor Cf is formed between the first comb-shaped electrode E1 and the second comb-shaped electrode E2.

A parasitic capacitance Ce is formed between the second comb-shaped electrode E2 and the lower rectangular electrode E4. Further, a parasitic capacitance Cf is formed between the lower rectangular electrode E4 and the semiconductor substrate 402.

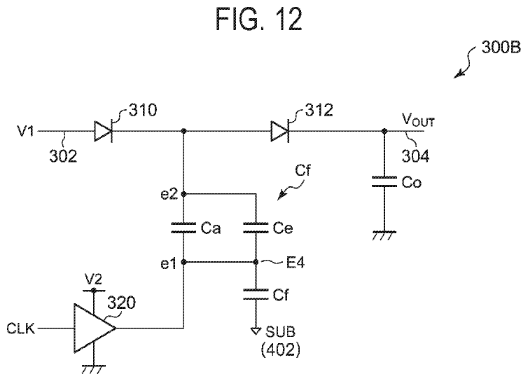

FIG. 12 is a circuit diagram of a charge pump circuit 300B that takes the parasitic capacitance into consideration. The flying capacitor Cf includes capacitances Ca, Ce, and Cf. The capacitance Ca is the inter-electrode capacitance Ca shown in FIG. 11, and the capacitances Ce and Cf are parasitic capacitances.

By connecting the lower rectangular electrode E4 to the first end e1 of the flying capacitor Cf, the parasitic capacitance Ce of the parasitic capacitances Ce and Cf of the flying capacitor Cf is connected in parallel with the inter-electrode capacitance Ca. In other words, the parasitic capacitance Ce can be effectively used as an effective capacitance of the flying capacitor Cf.

In this flying capacitor Cf, the parasitic capacitance Cf serves as a charge leakage path. The parasitic capacitance Cf is connected to the first end e1 of the flying capacitor Cf, i.e., the output node of the driver 320. The first end e1 of the flying capacitor Cf is a low impedance node. Therefore, the first end e1 of the flying capacitor Cf is difficult to be affected by the parasitic capacitance Cf, and leakage of charges is reduced compared with the comparative technique. Thus, it is possible to improve efficiency of the charge pump circuit 300B.

Next, modifications of Embodiment 2 will be described.

### Modification 2-1

In Embodiment 2 as well, the comb-shaped electrodes E1 and E2 may have a multilayer structure.

### Modification 2-2

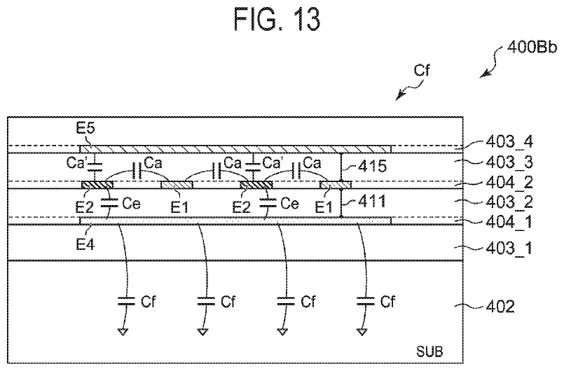

FIG. 13 is a cross-sectional view of a semiconductor integrated circuit 400Bb including a flying capacitor Cf according to Modification 2-2. This flying capacitor Cf further includes an upper rectangular electrode E5 formed in an uppermost metal wiring layer 404_3. The upper rectangular electrode E5 is electrically connected to the first comb-shaped electrode E1. A solid line 415 schematically indicates an electrical connection between the upper rectangular electrode E5 and the first comb-shaped electrode E1. Just like the lower rectangular electrode E4, the upper rectangular electrode E5 is a quadrangle that covers the formation region of the first comb-shaped electrode E1 and the second comb-shaped electrode E2.

In this modification, a capacitance Ca′ is also formed between the second comb-shaped electrode E2 and the upper rectangular electrode E5, which makes it possible to increase an effective capacitance of the flying capacitor Cf. Further, the upper rectangular electrode E5 has a larger area than the first comb-shaped electrode E1 and the second comb-shaped electrode E2. Therefore, an effect of reducing an impedance of the first end e1 of the flying capacitor Cf can be obtained, and leakage of charges to the semiconductor substrate 402 can be further reduced.

Next, a specific example of the semiconductor integrated circuit 400 will be described.

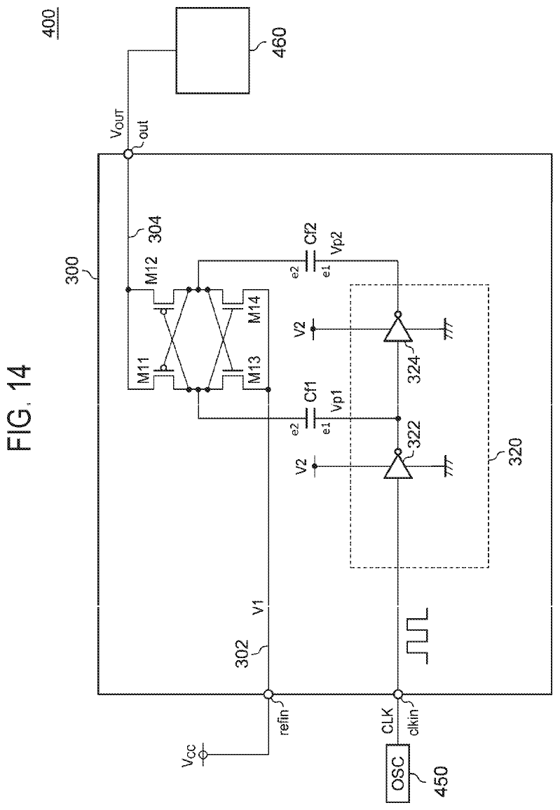

FIG. 14 is a circuit diagram of the semiconductor integrated circuit 400. The semiconductor integrated circuit 400 includes a charge pump circuit 300, an oscillator 450, and a load circuit 460. The oscillator 450 generates a clock signal CLK. The charge pump circuit 300 performs a switching operation in synchronization with the clock signal CLK, and steps up a power supply voltage Vcc to generate an output voltage Vour higher than power supply voltage Vcc. The output voltage Vour is supplied to the load circuit 460.

The charge pump circuit 300 includes a clock input node clkin, a reference input node refin, an output node out, an input line 302, an output line 304, first to fourth transistors M11 to M14, a first flying capacitor Cf1, a second flying capacitor Cf2, and a driver 320.

The clock signal CLK generated by the oscillator 450 is supplied to the clock input node clkin. The power supply voltage Vcc is supplied to the reference input node refin as a first voltage V1. The input line 302 is connected to the reference input node refin. The load circuit 460 is connected to the output line 304 via the output node out. Each of the first flying capacitor Cf1 and the second flying capacitor Cf2 has a first end and a second end. An output capacitor may be connected to the output line 304.

The first transistor M11 and the second transistor M12 are PMOS (Metal Oxide Semiconductor) transistors. The first transistor M11 has a first electrode (source) connected to the output line 304, and a second electrode (drain) connected to the second end of the first flying capacitor Cf1. A control electrode (gate) of the first transistor M11 is connected to the second end of the second flying capacitor Cf2.

The second transistor M12 has a first electrode (source) connected to the output line 304, and a second electrode (drain) connected to the second end of the second flying capacitor Cf2. A control electrode (gate) of the second transistor M12 is connected to the second end of the first flying capacitor Cf1.

The third transistor M13 and the fourth transistor M14 are NMOS transistors. The third transistor M13 has a first electrode (source) connected to the input line 302, and a second electrode (drain) connected to the second end of the first flying capacitor Cf1. A control electrode (gate) of the third transistor M13 is connected to the second end of the second flying capacitor Cf2.

The fourth transistor M14 has a first electrode (source) connected to the input line 302, a second electrode (drain) connected to the second end of the second flying capacitor Cf2, and a control electrode (gate) connected to the second end of the first flying capacitor Cf1.

The first transistor M11 and the second transistor M12 correspond to the rectifying element 310 shown in FIG. 1. The third transistor M13 and the fourth transistor M14 correspond to the rectifying element 312 shown in FIG. 1.

The driver 320 applies a first pulse voltage Vp1, which has a high level of the second voltage V2 (=Vcc), to the first end e1 of the first flying capacitor Cf1 in synchronization with the clock signal CLK. A low level of the first pulse voltage Vp1 may be a ground voltage or may be any voltage between the first voltage V1 and the ground voltage.

In addition, the driver 320 applies a second pulse voltage Vp2, which has a high level of the second voltage V2 (=Vcc) and has a phase opposite to the first pulse voltage Vp1, to the first end of the second flying capacitor Cf2 in synchronization with the clock signal CLK. The driver 320 includes a first inverter 322 and a second inverter 324.

The second voltage V2 is supplied to an upper power supply terminal of each of the first inverter 322 and the second inverter 324. A lower power supply terminal of each of the first inverter 322 and the second inverter 324 may be grounded, or an arbitrary voltage may be applied thereto.

The first inverter 322 inverts the clock signal CLK and applies it as the first pulse voltage Vp1 to the first end e1 of the first flying capacitor Cf1. The second inverter 324 inverts the first pulse voltage Vp1, which is an output of the first inverter 322, and applies it as the second pulse voltage Vp2 to the first end e1 of the second flying capacitor Cf2.

The above-described structures may be adopted for the flying capacitors Cf1 and Cf2.

Next, an application of the charge pump circuit 300 will be described. The charge pump circuit 300 may be used in a motor driver circuit.

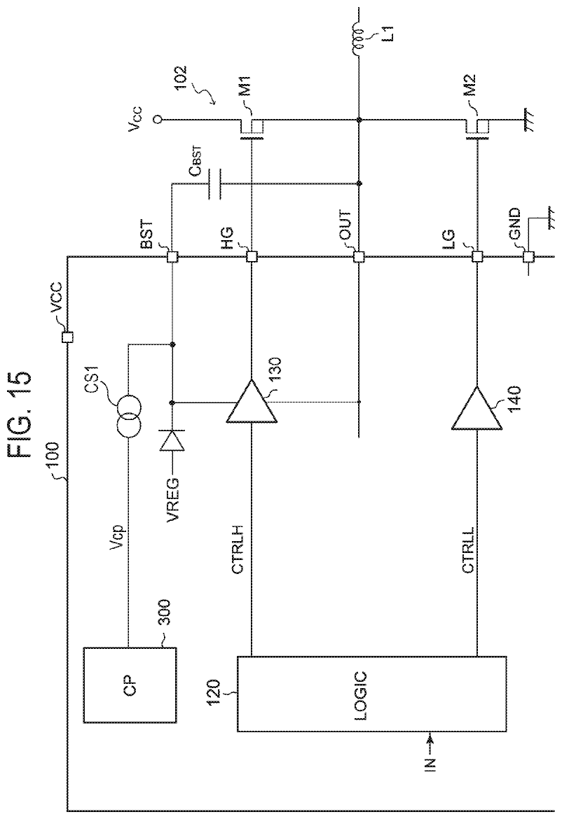

FIG. 15 is a circuit diagram of a motor driver circuit 100 including a charge pump circuit 300. The number of phases of a motor is not particularly limited and may be a single phase or multiple phases (e.g., three phases).

The motor driver circuit 100 is connected to a leg 102 of an inverter. The leg 102 includes a high-side transistor M1 as an upper arm and a low-side transistor M2 as a lower arm.

The motor driver circuit 100 includes a logic circuit 120, a high-side pre-driver 130, a low-side pre-driver 140, and a charge pump circuit 300.

The logic circuit 120 generates a control signal CTRLH, which instructs the high-side transistor M1 to be turned-on and turned-off, in response to an input signal IN. The logic circuit 120 also generates a control signal CTRLL, which instructs the low-side transistor M2 to be turned-on and turned-off, in response to the input signal IN.

The high-side pre-driver 130 drives the high-side transistor M1 in response to the control signal CTRLH. The low-side pre-driver 140 drives the low-side transistor M2 in response to the control signal CTRLL.

A bootstrap capacitor CBST is connected between a bootstrap terminal BST and a switching terminal OUT of the motor driver circuit 100.

When a switching operation is stopped, a bootstrap circuit cannot maintain a voltage at the bootstrap terminal BST. Therefore, the motor driver circuit 100 includes a trickle charge pump circuit. The trickle charge pump circuit includes the charge pump circuit 300 and a current source CS1.

The charge pump circuit 300 generates a step-up voltage Vcp. The current source CS1 operates using the step-up voltage Vcp as a power source and supplies a current to the BST terminal to charge it. Thus, it is possible to maintain an on state of the high-side transistor M1 even when the switching operation is stopped.

Application of the charge pump circuit 300 is not limited to the motor driver circuit, and the charge pump circuit 300 may be used in various driver circuits that drive an N-channel high-side transistor. More specifically, applications of the charge pump circuit 300 are not limited to driving a high-side transistor, and the charge pump circuit 300 may be used in various integrated circuits that require a voltage higher than a power supply voltage Vcc.

### (Supplementary Notes)

The following technique is disclosed in this specification.

### (Item 1)

A semiconductor integrated circuit in which a charge pump circuit is integrated on a semiconductor substrate,
wherein the charge pump circuit includes:
   a flying capacitor; and
   a driver configured to apply a switching voltage to one end of the flying capacitor,
wherein the flying capacitor includes a pair of comb-shaped electrodes, which are formed in a metal wiring layer and distanced from each other by a gap,
wherein a well is formed in the semiconductor substrate in a region overlapping with the flying capacitor, and
wherein the well is electrically connected to one of the pair of comb-shaped electrodes corresponding to the one end.

### (Item 2)

The semiconductor integrated circuit of Item 1, wherein the pair of comb-shaped electrodes has a multilayer structure.

### (Item 3)

The semiconductor integrated circuit of Item 1 or 2, wherein the flying capacitor further includes a rectangular electrode formed in an uppermost metal wiring layer.

### (Item 4)

The semiconductor integrated circuit of Item 3, wherein the rectangular electrode is electrically connected to one of the pair of comb-shaped electrodes corresponding to the one end.

### (Item 5)

A semiconductor integrated circuit in which a charge pump circuit is integrated on a semiconductor substrate,
wherein the charge pump circuit includes:
   a flying capacitor; and
   a driver configured to apply a switching voltage to one end of the flying capacitor,
wherein the flying capacitor includes:
   a pair of comb-shaped electrodes, which are formed in a metal wiring layer and distanced from each other by a gap; and
   a lower rectangular electrode formed in a layer below the metal wiring layer, and
wherein the lower rectangular electrode is electrically connected to one of the pair of comb-shaped electrodes corresponding to the one end.

### (Item 6)

The semiconductor integrated circuit of Item 5, wherein the pair of comb-shaped electrodes has a multilayer structure.

### (Item 7)

The semiconductor integrated circuit of Item 5 or 6, wherein the flying capacitor further includes an upper rectangular electrode formed in an uppermost metal wiring layer.

### (Item 8)

The semiconductor integrated circuit of Item 7, wherein the upper rectangular electrode is electrically connected to one of the pair of comb-shaped electrodes corresponding to the one end.

While certain embodiments have been described, these embodiments have been presented by way of example only and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor integrated circuit in which a charge pump circuit is integrated on a semiconductor substrate,
wherein the charge pump circuit includes:
a flying capacitor; and
a driver configured to apply a switching voltage to one end of the flying capacitor,
wherein the flying capacitor includes a pair of comb-shaped electrodes, which are formed in a metal wiring layer and distanced from each other by a gap,
wherein a well is formed in the semiconductor substrate in a region overlapping with the flying capacitor, and
wherein the well is electrically connected to one of the pair of comb-shaped electrodes corresponding to the one end.

2. The semiconductor integrated circuit of claim 1, wherein the pair of comb-shaped electrodes has a multilayer structure.

3. The semiconductor integrated circuit of claim 1, wherein the flying capacitor further includes a rectangular electrode formed in an uppermost metal wiring layer.

4. The semiconductor integrated circuit of claim 3, wherein the rectangular electrode is electrically connected to one of the pair of comb-shaped electrodes corresponding to the one end.

5. A semiconductor integrated circuit in which a charge pump circuit is integrated on a semiconductor substrate,
wherein the charge pump circuit includes:
a flying capacitor; and
a driver configured to apply a switching voltage to one end of the flying capacitor,
wherein the flying capacitor includes:
a pair of comb-shaped electrodes, which are formed in a metal wiring layer and distanced from each other by a gap; and
a lower rectangular electrode formed in a layer below the metal wiring layer, and
wherein the lower rectangular electrode is electrically connected to one of the pair of comb-shaped electrodes corresponding to the one end.

6. The semiconductor integrated circuit of claim 5, wherein the pair of comb-shaped electrodes has a multilayer structure.

7. The semiconductor integrated circuit of claim 5, wherein the flying capacitor further includes an upper rectangular electrode formed in an uppermost metal wiring layer.

8. The semiconductor integrated circuit of claim 7, wherein the upper rectangular electrode is electrically connected to one of the pair of comb-shaped electrodes corresponding to the one end.
